(19) United States
(12) Patent Application Publication
(10) Pub. No.: US 2026/0150596 A1
(43) Pub. Date: May 28, 2026

(54) SILICON OXIDATION FOR HIGH-VOLTAGE SUBSTRATE APPLICATIONS

(71) Applicant: Analog Devices, Inc., Wilmington, MA (US)

(72) Inventors: James G. Fiorenza, Carlisle, MA (US); F. Jacob Steigerwald, North Andover, MA (US); Daniel Piedra, Somerville, MA (US)

(21) Appl. No.: 19/296,649

(22) Filed: Aug. 11, 2025

Related U.S. Application Data
(60) Provisional application No. 63/725,354, filed on Nov. 26, 2024.

(51) Int. Cl. H01L 21/02; H10D 30/01; H10D 30/47

(52) U.S. Cl. CPC H10P 14/6522; H10D 30/015; H10D 30/471

(57) ABSTRACT

Techniques to convert a silicon layer into a silicon dioxide layer, such as by diffusing oxygen in an oxygen-rich region into the silicon layer to react with the silicon layer to form the silicon dioxide layer. As a result, the conductive silicon layer is removed and the electric field lines originating from the drain node no longer terminate in the silicon layer. Therefore, the electric field in gallium nitride (GaN) is significantly reduced, and a thinner GaN layer may be used for high-voltage devices.

### CLAIM OF PRIORITY

This application claims the benefit of priority to U.S. Provisional Application Ser. No. 63/725,354, titled “BURIED CHANNEL AIGaN BUFFER TRANSISTORS” to James G. Fiorenza et al., filed Nov. 26, 2024, which is incorporated by reference herein in its entirety.

### FIELD OF THE DISCLOSURE

This document pertains generally, but not by way of limitation, to semiconductor devices, and more particularly, to techniques for constructing gallium nitride devices.

### BACKGROUND

Gallium nitride (GaN) based semiconductors offer several advantages over other semiconductors as the material of choice for fabricating the next generation of transistors, or semiconductor devices, for use in both high-voltage and high-frequency applications. GaN based semiconductors, for example, have a wide bandgap that enable devices fabricated from these materials to have a high breakdown electric field and to be robust to a wide range of temperatures.

The two-dimensional electron gas (2DEG) channels formed by GaN based heterostructures generally have high electron mobility, making devices fabricated using these structures useful in power-switching and amplification systems. GaN based semiconductors, however, are typically used to fabricate depletion mode (or normally on) devices, which may have limited use in many of these systems, such as due to the added circuit complexity required to support such devices.

### SUMMARY OF THE DISCLOSURE

This disclosure describes techniques to convert a silicon layer into a silicon dioxide layer, such as by diffusing oxygen in an oxygen-rich region into the silicon layer to react with the silicon layer to form the silicon dioxide layer. As a result, the conductive silicon layer is removed and the electric field lines originating from the drain node no longer terminate in the silicon layer. Therefore, the electric field in the GaN is significantly reduced, and a thinner GaN layer may be used for high-voltage devices, such as 650V-1200V.

In some aspects, this disclosure is directed to a method of forming a transistor device, the method comprising: forming an insulator layer over an engineered substrate, wherein the engineered substrate includes material lacking a single crystal lattice structure, and wherein the material has a coefficient of thermal expansion approximately matched to a coefficient of thermal expansion of a first semiconductor material layer; forming an oxygen-rich region in the insulator layer; forming a silicon layer over the oxygen-rich region, wherein the silicon layer has a first bandgap; forming the first semiconductor material layer over the silicon layer; and forming a second semiconductor material layer over the first semiconductor material layer to diffuse at least a portion of oxygen in the oxygen-rich region into the silicon layer to react with the silicon layer to form a silicon dioxide layer, wherein the silicon dioxide layer has a second bandgap that is greater than the first bandgap.

In some aspects, this disclosure is directed to a compound semiconductor heterostructure transistor device comprising: a substrate over which a first insulator layer of silicon dioxide or silicon nitride is formed; a second insulator layer of silicon dioxide formed over the first insulator layer, wherein the second insulator layer is formed from a layer of silicon; a first semiconductor material layer formed over the second insulator layer of silicon dioxide; and a second semiconductor material layer formed over the first semiconductor material layer to form a compound semiconductor heterostructure having a two-dimensional electron gas (2DEG) channel, wherein the 2DEG channel is more conductive than either the first semiconductor material layer or the second semiconductor material layer.

In some aspects, this disclosure is directed to a compound semiconductor heterostructure transistor device comprising: a first insulator layer formed over an engineered substrate, wherein the engineered substrate includes material lacking a single crystal lattice structure, and wherein the material has a coefficient of thermal expansion approximately matched to a coefficient of thermal expansion of a second semiconductor material layer; a second insulator layer of silicon dioxide formed over the first insulator layer, wherein the second insulator layer is formed from a layer of silicon; a first semiconductor material layer formed over the second insulator layer of silicon dioxide; and a second semiconductor material layer formed over the first semiconductor material layer.

### BRIEF DESCRIPTION OF THE DRAWINGS

In the drawings, which are not necessarily drawn to scale, like numerals may describe similar components in different views. The drawings illustrate generally, by way of example, but not by way of limitation, various embodiments discussed in the present document.

FIG. 1 depicts an example of a transistor device in accordance with this disclosure.

FIG. 2 depicts an example of a transistor device of FIG. 1 after a portion of oxygen in an oxygen-rich region diffuses into a silicon layer to react with silicon in the silicon layer to form a silicon dioxide layer in accordance with this disclosure.

FIG. 3 depicts another example of the transistor device of FIG. 1 after a portion of oxygen in an oxygen-rich region diffuses into the silicon layer of FIG. 1 to react with silicon in the silicon layer to form a silicon dioxide layer in accordance with this disclosure.

FIG. 4 is a flow diagram of an example of a method of forming a transistor device.

### DETAILED DESCRIPTION

The substrate of a transistor device is a foundational semiconductor layer that provides mechanical support and may also serve an electrical function such as the body terminal. An engineered substrate is a specially designed material that facilitates the growth of semiconductor layers, such as gallium nitride (GaN), by addressing challenges associated with lattice mismatch and thermal expansion mismatch. In one example, the engineered substrate includes a polycrystalline aluminum nitride (or AlN) wafer. Polycrystalline AlN (or “poly-AlN”) is not a single crystal, so it does not have a crystal lattice. Crystals cannot be grown on non-crystals. So, a thin crystalline silicon layer (Si), such as a silicon layer about 100 nanometers (nm) thick, is included in the engineered substrate. The poly-AlN provides a coefficient of thermal expansion (CTE) approximately matched to GaN, and the crystalline silicon layer offers a suitable lattice structure for the growth of aluminum nitride and GaN. This combination alleviates growth challenges, reduces defects, and enhances the quality of the semiconductor layers.

The present inventors have recognized that the thin crystalline silicon layer may cause a problem in a high-voltage device made on top of the wafer. Electric field lines originate on the drain node of the transistor device and end on the silicon layer. The field strength is determined by the GaN epitaxy thickness: electric field=drain voltage divided by the GaN epitaxial layer (“epi”) thickness. This means that the GaN epi is desirably thick for a high-voltage device. A related example may be seen in commercial GaN devices using silicon and sapphire substrates. Silicon is used for 650 volt (V) GaN devices. Sapphire is used for 1200 V GaN devices because the electric field may spread into the substrate and so the GaN may be thinner than if silicon was used.

This disclosure describes techniques to convert a silicon layer into a silicon dioxide layer, such as by diffusing oxygen in an oxygen-rich region into the silicon layer to react with the silicon layer to form the silicon dioxide layer. As a result, the conductive silicon layer is removed and the electric field lines originating from the drain node no longer terminate in the silicon layer. Therefore, the electric field in the GaN is significantly reduced, and a thinner GaN layer may be used for high-voltage devices, such as 650V-1200V.

Previous techniques for forming transistor devices often relied on a layer transfer process to integrate a thin silicon layer onto a polycrystalline aluminum nitride (poly-AlN) substrate. With this technique, a silicon layer, such as around 100 nm thick, was bonded to the substrate using intermediate layers such as silicon dioxide (SiO₂) or silicon nitride (SiN). The layer transfer process enabled the use of silicon as a lattice structure for subsequent epitaxial growth of wide bandgap materials like GaN or AlGaN. However, this process introduced challenges in high-voltage devices because the electric field terminates at the conductive silicon layer and, as a result, a thicker GaN layer is needed to prevent breakdown. Additionally, the silicon layer imposed its lattice constant on the GaN growth, which limits the flexibility of lattice matching. Although layer transfer techniques provide a way to integrate silicon with poly-AlN substrates, these layer transfer techniques are constrained by the inherent limitations of silicon's low bandgap (1.12 eV) and low breakdown field (0.3 MV/cm), which restrict the performance of high-voltage devices.

As used in this disclosure, a GaN-based compound semiconductor material may include a chemical compound of elements including GaN and one or more elements from different groups in the periodic table. Such chemical compounds may include a pairing of elements from group 13 (i.e., the group comprising boron (B), aluminum (Al), gallium (Ga), indium (In), and thallium (Tl)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. In an example, a semiconductor device may be fabricated from GaN and aluminum indium gallium nitride (AlInGaN).

Heterostructures described herein may be formed as AlN/GaN/AlN hetero-structures, InAlN/GaN heterostructures, AlGaN/GaN heterostructures, or heterostructures formed from other combinations of group 13 and group 15 elements. These heterostructures may form a two-dimensional electron gas (2DEG) at the interface of the compound semiconductors that form the heterostructure, such as the interface of GaN and AlGaN. The 2DEG may form a conductive channel of electrons that may be controllably depleted, such as by an electric field formed by a buried layer of p-type material disposed below the channel. The conductive channel of electrons that may also be controllably enhanced, such as by an electric field formed by a gate terminal disposed above the channel to control a current through the semiconductor device. Semiconductor devices formed using such conductive channels may include high electron mobility transistors.

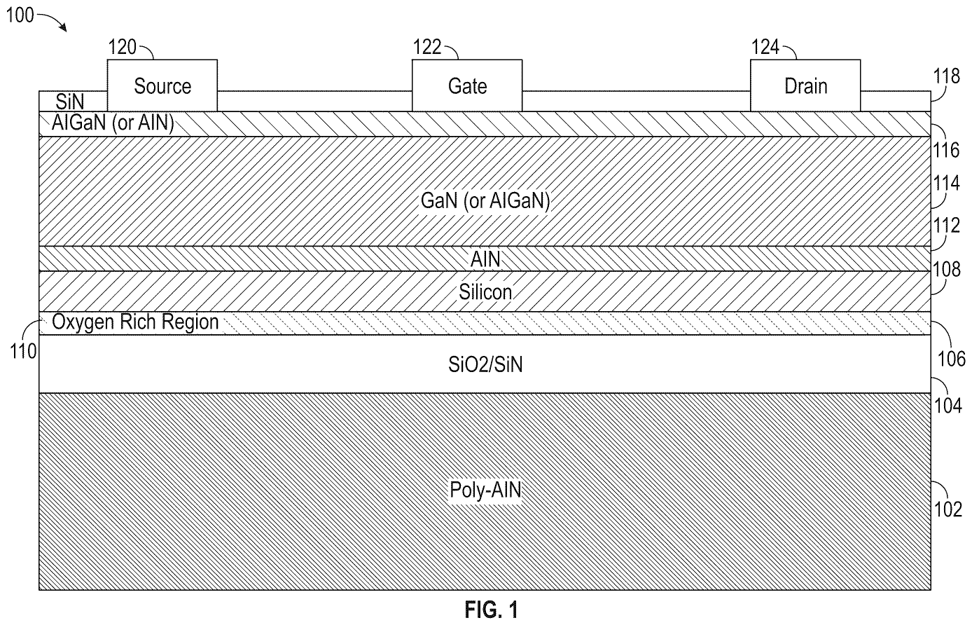

FIG. 1 depicts an example of a transistor device in accordance with this disclosure. The transistor device 100 includes an engineered substrate 102, such as polycrystalline aluminum nitride (“poly-AlN”), polycrystalline silicon carbide (SiC), or polycrystalline silicon (Si). Engineered substrates may provide better lattice matching or CTE matching for growth of GaN, which may help reduce or eliminate growth challenges that may be present if silicon were used as the substrate. An insulator layer 104, such as a silicon dioxide layer (SiO₂) or silicon nitride layer (SiN), is formed over the engineered substrate 102.

In accordance with this disclosure, an oxygen-rich region 106 is formed in the insulator layer 104. For example, in FIG. 1, the oxygen-rich region 106 is formed in the top half of the oxygen-rich region 106 and adjacent to a silicon layer 108. In some examples, the oxygen-rich region 106 may be formed by implanting oxygen into the insulator layer 104 before forming the silicon layer 108 to increase a concentration of the oxygen at an interface 110 between the insulator layer 104 and the silicon layer 108. In other examples, the oxygen-rich region 106 may be formed by implanting oxygen into the insulator layer 104 after forming the silicon layer 108 to increase a concentration of the oxygen at the interface 110 between the insulator layer and the silicon layer 108. Higher energy may be needed for implantation after the silicon layer is formed in order to drive the ions through the silicon so they end up at the interface. Lower energy may be needed for implantation before the silicon is formed because there is nothing to drive the ions through for them to end up at the surface. The implantation may be tuned such that there is a high concentration of oxygen, such as between about 1E12 cm⁻² and about 1E19 cm⁻², at the interface 110.

As mentioned above, the silicon layer 108 is formed over the oxygen-rich region 106. Then, a nucleation layer 112 is formed over the silicon layer 108. In some examples, the nucleation layer 112 includes aluminum nitride (AlN). The nucleation layer 112 helps provide a high-quality crystalline structure upon which semiconductor material, such as GaN or AlGaN, may be grown. Although AlN is a very wide bandgap semiconductor, in this context, it is not used for active electronic behavior but rather to reduce lattice mismatch and improve epitaxial layer quality.

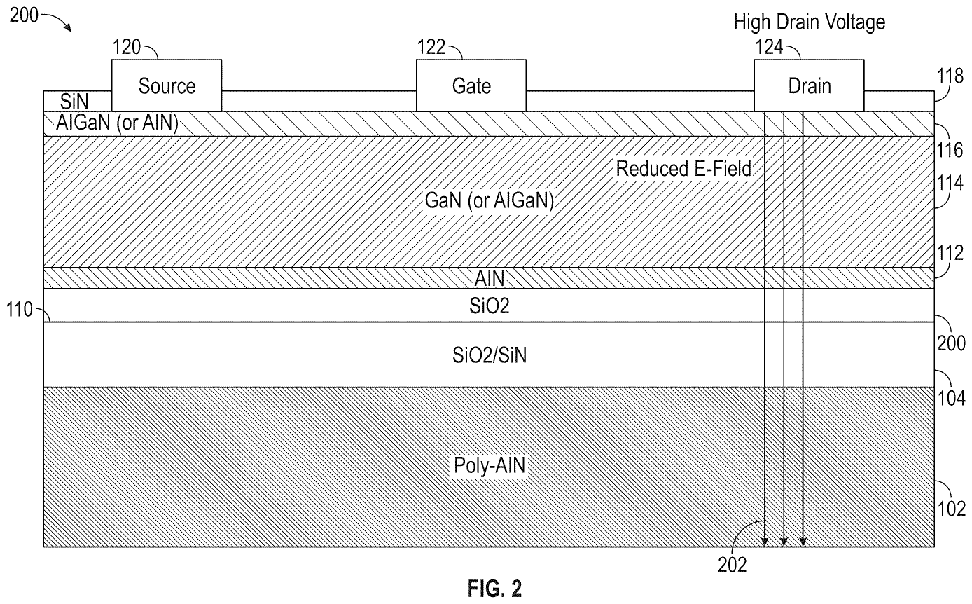

The transistor device 100 may include a first semiconductor material layer 114. The engineered substrate 102 may have a CTE approximately matched to a coefficient of thermal expansion of the first semiconductor material layer 114. In some examples, the first semiconductor material layer 114 includes GaN. In other examples, the first semiconductor material layer 114 includes aluminum gallium nitride (AlGaN). In some examples, the first semiconductor material layer 114, e.g., GaN, is formed in a reactor, such as a Metal-Organic Chemical Vapor Deposition (MOCVD) reactor, at high temperatures around 1000° C. to 1100° C. During the formation of the first semiconductor material layer 114, at least a portion of oxygen in the oxygen-rich region 106 diffuses into the silicon layer 108 and reacts with the silicon in the silicon layer 108 to form a silicon dioxide layer (shown in FIG. 2).

The transistor device 100 may include a second semiconductor material layer 116 formed over the first semiconductor material layer 114. In some examples, the second semiconductor material layer 116 includes AlGaN. In other examples, the second semiconductor material layer 116 includes AlN. In some examples, the second semiconductor material layer 116 of AlGaN is formed over the first semiconductor material layer 114 of GaN. In other examples, the second semiconductor material layer 116 of AlN is formed over the first semiconductor material layer 114 of AlGaN.

A passivation layer 118 is formed over the second semiconductor material layer 116. In some examples, the passivation layer 118 includes SiN.

Transistor device contacts may then be formed over the passivation layer 118, including a source contact 120, a gate contact 122, and a drain contact 124.

FIG. 2 depicts an example of the transistor device 100 of FIG. 1 after a portion of oxygen in an oxygen-rich region diffuses into the silicon layer 108 of FIG. 1 to react with silicon in the silicon layer to form a silicon dioxide layer (another insulator layer) in accordance with this disclosure. As seen in FIG. 2, the oxygen of the oxygen-rich region 106 of FIG. 1 has diffused into the silicon layer 108 of FIG. 1 (an insulator layer), reacted with the silicon of the silicon layer 108, and formed the silicon dioxide layer 200 (an insulator layer) from the silicon layer 108.

The silicon layer 108 of FIG. 1 has a first bandgap (about 1.12 electron volts (eV)), and the silicon dioxide layer 200 has a second bandgap (about 8.9 eV) that is greater than the first bandgap. Silicon dioxide has a breakdown field of about 10 MV/cm, which is much higher than that of silicon, which has a breakdown field of about 0.3 MV/cm. By converting the silicon layer 108 of FIG. 1 to the silicon dioxide layer 200 of FIG. 2, the transistor device 100 is able to support high electric fields and, as such, enhance performance in high-voltage applications. The electric field 202 no longer stops at the silicon layer 108 of FIG. 1 but instead extends through the transistor device 100 to the engineered substrate 102.

The electric field 202 originates at the drain contact 124 and terminates at the engineered substrate 102. As mentioned above, the strength of the electric field in the first semiconductor material layer 114, e.g., the GaN layer, is determined by the voltage applied to the drain contact 124 and the thickness of the first semiconductor material layer 114. Now that the electric field 202 terminates at the engineered substrate 102, the first semiconductor material layer 114, e.g., GaN layer, may be made thinner than before because the electric field strength is spread throughout the transistor device 100 and is no longer concentrated in the first semiconductor material layer 114, in contrast to when the silicon layer 108 was present.

In some examples, the aluminum fraction in one or both of the first semiconductor material layer 114 and the second semiconductor material layer 116 may be tuned by adjusting its percentage. In a non-limiting example, the aluminum fraction in the second semiconductor material layer 116 may be between 80-85% and/or the aluminum fraction in the first semiconductor material layer 114 may be about 60%. Tuning the aluminum fraction in this manner results in a high critical field in AlGaN, for example, and, as such, the electric field that AlGaN may sustain may be much higher than that of GaN. Using these techniques, the transistor device 100 may sustain higher electric fields than previously possible.

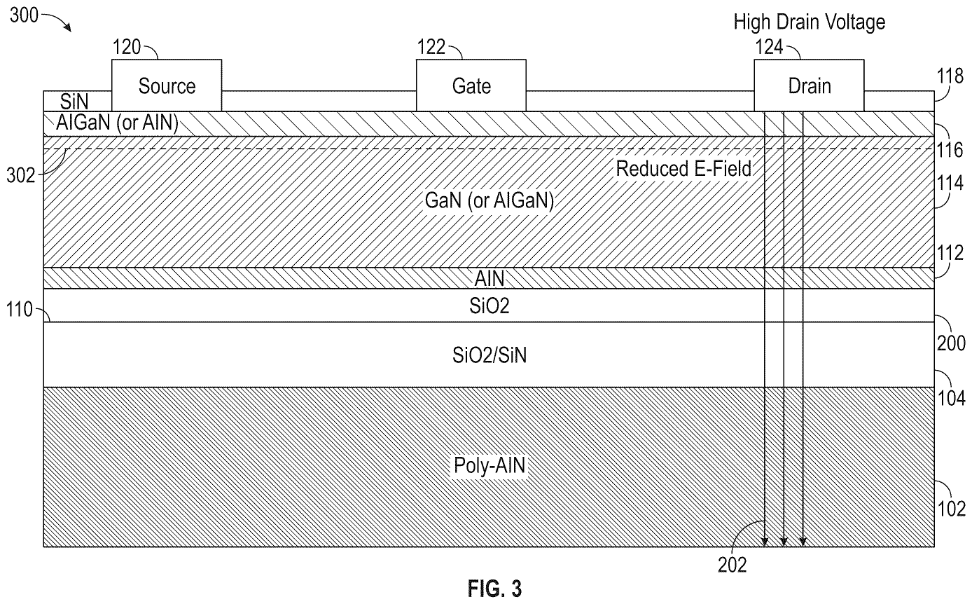

FIG. 3 depicts another example of the transistor device 100 of FIG. 1 after a portion of oxygen in an oxygen-rich region diffuses into the silicon layer 108 of FIG. 1 to react with silicon in the silicon layer to form a silicon dioxide layer (another insulator layer) in accordance with this disclosure. In FIG. 3, the first semiconductor material layer 114, such as GaN or AlGaN, is formed over the silicon layer 108. A second semiconductor material layer, such as AlGaN or AlN, is formed over the first semiconductor material layer 114 to form a compound semiconductor heterostructure of a compound semiconductor heterostructure transistor device having a 2DEG channel 302, where the 2DEG channel is more conductive than either the first semiconductor material layer 114 or the second semiconductor material layer 116. The transistor device 300 includes a gate contact 122 in contact with the second semiconductor material layer, and a drain contact 124 and a source contact 120 in contact with the second semiconductor material layer 116 or the 2DEG channel 302.

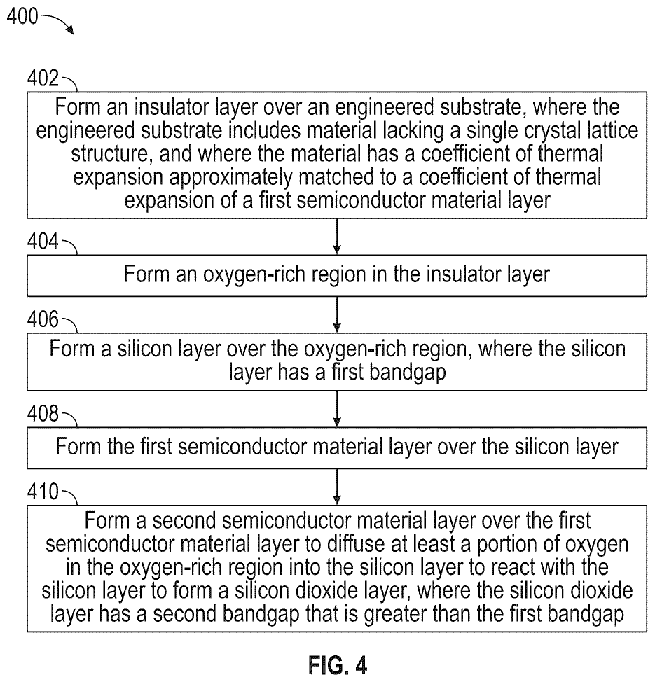

FIG. 4 is a flow diagram of an example of a method 400 of forming a transistor device. At block 402, the method 400 includes forming an insulator layer over an engineered substrate, where the engineered substrate includes material lacking a single crystal lattice structure, and where the material has a coefficient of thermal expansion approximately matched to a coefficient of thermal expansion of a first semiconductor material layer. In some examples, forming the insulator layer over the engineered substrate includes forming a silicon dioxide layer over the engineered substrate. In some examples, forming the insulator layer over the engineered substrate includes forming a silicon nitride layer over the engineered substrate.

In some examples, the engineered substrate includes polycrystalline aluminum nitride or polycrystalline silicon carbide. In some examples, the first semiconductor material layer includes gallium nitride or aluminum gallium nitride, and the second semiconductor material layer includes aluminum gallium nitride or aluminum nitride.

In some examples, the transistor device is a compound semiconductor heterostructure transistor device, and forming the second semiconductor material layer over the first semiconductor material layer forms a compound semiconductor heterostructure having a two-dimensional electron gas (2DEG) channel, where the 2DEG channel is more conductive than either the first semiconductor material layer or the second semiconductor material layer.

At block 404, the method 400 includes forming an oxygen-rich region in the insulator layer. In some examples, forming the oxygen-rich region includes implanting oxygen into the insulator layer before forming the silicon layer to increase a concentration of the oxygen at an interface between the insulator layer and the silicon layer. In some examples, implanting oxygen into the insulator layer after forming the silicon layer to increase a concentration of the oxygen at an interface between the insulator layer and the silicon layer.

At block 406, the method 400 includes forming a silicon layer over the oxygen-rich region, where the silicon layer has a first bandgap. At block 408, the method 400 includes forming the first semiconductor material layer over the silicon layer. At block 410, the method 400 includes forming a second semiconductor material layer over the first semiconductor material layer to diffuse at least a portion of oxygen in the oxygen-rich region into the silicon layer to react with the silicon layer to form a silicon dioxide layer, where the silicon dioxide layer has a second bandgap that is greater than the first bandgap.

In some examples, the method 400 includes a separate annealing process after the oxygen implantation but before forming the first semiconductor material layer, e.g., GaN, over the silicon layer. Such an annealing process may improve the crystalline quality of the silicon layer (by annealing out any damage done by the implant) and thus improve the crystalline quality of the GaN layer. Additionally, by having this separate annealing step, the desired or optimal temperature for the diffusion of the oxygen may be independently tuned and coupled to the growth temperature of the GaN.

### Various Notes

Each of the non-limiting claims or examples described herein may stand on its own, or may be combined in various permutations or combinations with one or more of the other examples.

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described. However, the present inventors also contemplate examples in which only those elements shown or described are provided. Moreover, the present inventors also contemplate examples using any combination or permutation of those elements shown or described (or one or more claims thereof), either with respect to a particular example (or one or more claims thereof), or with respect to other examples (or one or more claims thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more claims thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

What is claimed is:

1. A method of forming a transistor device, the method comprising:
forming an insulator layer over an engineered substrate, wherein the engineered substrate includes material lacking a single crystal lattice structure, and wherein the material has a coefficient of thermal expansion approximately matched to a coefficient of thermal expansion of a first semiconductor material layer;
forming an oxygen-rich region in the insulator layer;
forming a silicon layer over the oxygen-rich region, wherein the silicon layer has a first bandgap;
forming the first semiconductor material layer over the silicon layer; and
forming a second semiconductor material layer over the first semiconductor material layer to diffuse at least a portion of oxygen in the oxygen-rich region into the silicon layer to react with the silicon layer to form a silicon dioxide layer, wherein the silicon dioxide layer has a second bandgap that is greater than the first bandgap.

2. The method of claim 1, wherein forming the oxygen-rich region includes:
implanting oxygen into the insulator layer before forming the silicon layer to increase a concentration of the oxygen at an interface between the insulator layer and the silicon layer.

3. The method of claim 1, wherein forming the oxygen-rich region includes:
implanting oxygen into the insulator layer after forming the silicon layer to increase a concentration of the oxygen at an interface between the insulator layer and the silicon layer.

4. The method of claim 1, wherein forming the insulator layer over the engineered substrate includes:
forming a silicon dioxide layer over the engineered substrate.

5. The method of claim 1, forming the insulator layer over the engineered substrate includes:
forming a silicon nitride layer over the engineered substrate.

6. The method of claim 1, wherein the first semiconductor material layer includes gallium nitride or aluminum gallium nitride, and wherein the second semiconductor material layer includes aluminum gallium nitride or aluminum nitride.

7. The method of claim 1, wherein the engineered substrate includes polycrystalline aluminum nitride or polycrystalline silicon carbide.

8. The method of claim 1, wherein the transistor device is a compound semiconductor heterostructure transistor device, and wherein forming the second semiconductor material layer over the first semiconductor material layer forms a compound semiconductor heterostructure having a two-dimensional electron gas (2DEG) channel, wherein the 2DEG channel is more conductive than either the first semiconductor material layer or the second semiconductor material layer.

9. A compound semiconductor heterostructure transistor device comprising:
a substrate over which a first insulator layer of silicon dioxide or silicon nitride is formed;
a second insulator layer of silicon dioxide formed over the first insulator layer, wherein the second insulator layer is formed from a layer of silicon;
a first semiconductor material layer formed over the second insulator layer of silicon dioxide; and
a second semiconductor material layer formed over the first semiconductor material layer to form a compound semiconductor heterostructure having a two-dimensional electron gas (2DEG) channel, wherein the 2DEG channel is more conductive than either the first semiconductor material layer or the second semiconductor material layer.

10. The compound semiconductor heterostructure transistor device of claim 9, wherein the substrate is an engineered substrate that includes material lacking a single crystal lattice structure, and wherein the material has a coefficient of thermal expansion approximately matched to a coefficient of thermal expansion of the first semiconductor material layer.

11. The compound semiconductor heterostructure transistor device of claim 10, wherein the engineered substrate includes polycrystalline aluminum nitride or polycrystalline silicon carbide.

12. The compound semiconductor heterostructure transistor device of claim 9, further comprising:
a nucleation layer formed between the first semiconductor material layer and the second insulator layer.

13. The compound semiconductor heterostructure transistor device of claim 12, wherein the nucleation layer includes aluminum nitride.

14. The compound semiconductor heterostructure transistor device of claim 9, wherein the first semiconductor material layer includes gallium nitride or aluminum gallium nitride, and wherein the second semiconductor material layer includes aluminum gallium nitride or aluminum nitride.

15. The compound semiconductor heterostructure transistor device of claim 9, further comprising:
a gate contact in contact with the second semiconductor material layer; and
a drain contact and a source contact in contact with the second semiconductor material layer or the 2DEG channel.

16. A compound semiconductor heterostructure transistor device comprising:
a first insulator layer formed over an engineered substrate, wherein the engineered substrate includes material lacking a single crystal lattice structure, and wherein the material has a coefficient of thermal expansion approximately matched to a coefficient of thermal expansion of a second semiconductor material layer;
a second insulator layer of silicon dioxide formed over the first insulator layer, wherein the second insulator layer is formed from a layer of silicon;
a first semiconductor material layer formed over the second insulator layer of silicon dioxide; and
a second semiconductor material layer formed over the first semiconductor material layer.

17. The compound semiconductor heterostructure transistor device of claim 16, wherein the first semiconductor material layer includes gallium nitride or aluminum gallium nitride, and wherein the second semiconductor material layer includes aluminum gallium nitride or aluminum nitride.

18. The compound semiconductor heterostructure transistor device of claim 16, wherein the engineered substrate includes polycrystalline aluminum nitride or polycrystalline silicon carbide.

19. The compound semiconductor heterostructure transistor device of claim 16, further comprising:
a gate contact in contact with the second semiconductor material layer; and
drain and source contacts in contact with the second semiconductor material layer or the 2DEG channel.

20. The compound semiconductor heterostructure transistor device of claim 16, wherein the first semiconductor material layer and the second semiconductor material layer form a compound semiconductor heterostructure having a two-dimensional electron gas (2DEG) channel, wherein the 2DEG channel is more conductive than either the first semiconductor material layer or the second semiconductor material layer.
